(19) United States
(12) Patent Application Publication
(10) Pub. No.: US 2026/0209030 A1
(43) Pub. Date: Jul. 23, 2026

(54) NANO-MEMBRANE, ELECTRONIC DEVICE INCLUDING THE SAME, AND METHOD FOR MANUFACTURING THE NANO-MEMBRANE

(71) Applicant: KOLON INDUSTRIES, INC., Seoul (KR)

(72) Inventors: Sung Jin KIM, Seoul (KR); Jeong Young CHOI, Seoul (KR); Yu Kyung CHO, Seoul (KR); Samuel CHOI, Seoul (KR); Heung Ryul OH, Seoul (KR); Jun Young PARK, Seoul (KR)

(21) Appl. No.: 19/142,676

(22) PCT Filed: Dec. 21, 2023
(86) PCT No.: PCT/KR2023/021268

§ 371 Date: Jun. 24, 2025

(30) Foreign Application Priority Data
Dec. 29, 2022 (KR) 10-2022-0189747
Dec. 15, 2023 (KR) 10-2023-0183740

(51) Int. Cl. B81B 7/00; B01D 69/12; B01D 71/64

(52) U.S. Cl. CPC B81B 7/0038; B01D 69/12; B01D 71/641; B01D 71/643; B01D 2323/39; B81B 2201/0257; B81B 2203/0127

(57) ABSTRACT

The present disclosure relates to a nano-membrane formed of polyimide fibers, wherein the nano-membrane comprises an oil-repellent coating layer on a surface or a back surface thereof, the nano-membrane has a contact angle of 90 degrees or more for silicone oil with a surface tension of 20 dyne/cm measured according to ASTM D 5946, and the nano-membrane has a dust collection efficiency of 95% or more according to the following measurement method, a method for manufacturing the same, and a nano-membrane assembly including the same. [Measurement Method] Dust size: 0.6 μm; Air flow rate: 32 l/min; Measured according to AFT 8130 with a measurement area of 100 cm².

### TECHNICAL FIELD

The present disclosure relates to a nano-membrane excellent in dust collection efficiency and water resistance, an electronic device including the same, and a method for manufacturing the nano-membrane.

### BACKGROUND ART

Recently, electronic devices, for example, communication equipment such as smartphones, are becoming smaller, more integrated, and lower in power consumption.

Communication equipment such as smartphones has a micro electro mechanical system (MEMS) embedded therein, and various electronic components exist inside the MEMS. Various studies on encapsulation materials for preventing these electronic components from being contaminated by external pollutants have been continuously conducted.

However, encapsulation materials that have been successfully commercialized to date still lack dust collection efficiency and oil repellency, so that moisture such as saliva and rainwater, and foreign substances such as dust, enter the MEMS during use, causing failure of electronic components.

To solve these problems, attempts were made to improve dust collection efficiency by reducing porosity, but this encountered a limitation of a significant increase in sound transmission loss. Methods of reducing porosity or laminating a water-repellent layer on the membrane surface to prevent the ingress of moisture and dust have been proposed, but in these cases as well, limitations due to increased sound transmission loss and decreased air permeability were encountered.

In addition, a method of manufacturing fibers by mixing an oil-repellent material during fiber production has also been devised. However, MEMS manufacturing processes are often performed at high temperatures of 280° C. or higher, and conventional polymers have limitations due to the nature of organic materials, such as thermal shrinkage or melting of the membrane at high temperatures, and carbonization of the oil-repellent material, leading to membrane deformation.

Accordingly, there is still a demand for a dust-proof and oil-repellent nano-membrane that can sufficiently withstand the manufacturing process of micro electro mechanical systems (MEMS) performed at high temperatures of 280° C. or higher, maintain the sound transmission loss rate, and simultaneously have improved dust collection efficiency, water resistance, and oil resistance.

### DISCLOSURE OF THE INVENTION

### Technical Problem

An object of the present disclosure is to provide a nano-membrane having high heat resistance, dust collection efficiency, and oil repellency without showing a decrease in air/acoustic permeability.

### Technical Solution

According to one aspect, a nano-membrane formed of polyimide fibers is provided, wherein the nano-membrane includes an oil-repellent coating layer on a surface or a back surface thereof, the nano-membrane has a contact angle of 90 degrees or more for silicone oil with a surface tension of 20 dyne/cm measured according to ASTM D 5946, and the nano-membrane has a dust collection efficiency of 95% or more according to the following measurement method.

### [Measurement Method]

Dust size: 0.6 μm; Air flow rate: 32 l/min; Measured according to AFT 8130 with a measurement area of 100 cm².

According to one embodiment, the membrane may be manufactured by electrospinning.

According to one embodiment, the oil-repellent coating layer may include at least one selected from the group consisting of a fluorine-based compound, a silicone-based compound, and a hydrocarbon-based compound.

According to one embodiment, the fluorine-based compound may include fluoroalkyl acrylate copolymer, dimethyl perfluorobutylethyl, methyl perfluorobutylethyl, Fluoroalkylether copolymer, Perfluoro compound, or a combination thereof.

According to one embodiment, the silicone-based compound may include methyl vinyl siloxane copolymer, or a combination thereof.

According to one embodiment, the hydrocarbon-based compound may include a C10-18 hydrocarbon compound, or a combination thereof.

According to one embodiment, the polyimide fiber may include polyethyleneimine, polyamide-imide, polyetherimide, or a combination thereof.

According to one embodiment, the nano-membrane may have a thermal shrinkage rate of 1% or less at 300° C.

According to one embodiment, the nano-membrane may have a weight loss rate of 1 wt % or less at 300° C.

According to one embodiment, the nano-membrane may have a sound transmission loss of less than 5 dB/Pa at a 94 dB reference.

According to one aspect, a nano-membrane assembly is provided, including: the nano-membrane; and an adhesive layer interposed between the substrate and the nano-membrane.

According to one aspect, an electronic device including the nano-membrane is provided.

According to one aspect, a method for manufacturing a nano-membrane is provided, including: an electrospinning step of electrospinning a polyamic acid solution to prepare a precursor; a processing step of adjusting the density and thickness of the precursor; a converting step of determining the shape of the precursor; and a step of imidizing the converted precursor to obtain a nano-membrane precursor; and a step of treating the nano-membrane precursor with an oil-repellent finishing agent to introduce functional groups to the surface, wherein the oil-repellent finishing agent is a solution containing 1 to 20 wt % of at least one selected from the group consisting of a fluorine-based compound, a silicone-based compound, and a hydrocarbon-based compound, the imidization is performed at 200 to 500° C. for 10 to 30 minutes, in the electrospinning step, air is blown in the direction in which the precursor is discharged, and the nano-membrane has a dust collection efficiency of 95% or more according to the following measurement method:

### [Measurement Method]

Dust size: 0.6 μm; Air flow rate: 32 l/min; Measured according to AFT 8130 with a measurement area of 100 cm².

### Advantageous Effects

The nano-membrane according to the present disclosure is made of polyimide fibers formed by electrospinning a polyimide precursor, so that quality degradation does not occur even in a high-temperature process.

In addition, due to the oil-repellent coating layer formed on the surface or the back surface, the passage of moisture is effectively suppressed by having a contact angle of 90 degrees or more for silicone oil with a surface tension of 20 dyne/cm measured according to ASTM D 5946, and the passage of contaminants can be effectively prevented by having a dust collection efficiency of 95% or more.

### BRIEF DESCRIPTION OF THE DRAWINGS

FIG. 1 is a schematic diagram illustrating a nano-membrane assembly according to one embodiment of the present disclosure;

FIG. 2 is a top view illustrating a nano-membrane assembly manufactured according to one embodiment of the present disclosure; and

FIG. 3 is a view illustrating the results of an oil repellency test for nano-membranes prepared in Example 1 and Comparative Example 1.

### BEST MODE FOR CARRYING OUT THE INVENTION

Hereinafter, what is described as “upper part” or “upper” may include not only what is in direct contact and immediately above, but also what is above without contact. Singular expressions include plural expressions unless the context clearly dictates otherwise. Also, when a part “includes” a certain component, it means that it can further include other components, not excluding other components, unless specifically stated to the contrary.

The use of “the foregoing” and similar directive terms may apply to both singular and plural. Unless the order of steps constituting a method is explicitly stated or stated to the contrary, these steps may be performed in a suitable order and are not necessarily limited to the described order.

As used herein, the terms “comprise,” “comprising,” “formed,” “has,” “having,” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Also, unless expressly stated to the contrary, “or” refers to an inclusive “or” and not to an exclusive “or.”

The use of all examples or exemplary terms is merely for the purpose of explaining the technical idea in detail, and the scope is not limited by these examples or exemplary terms unless limited by the claims.

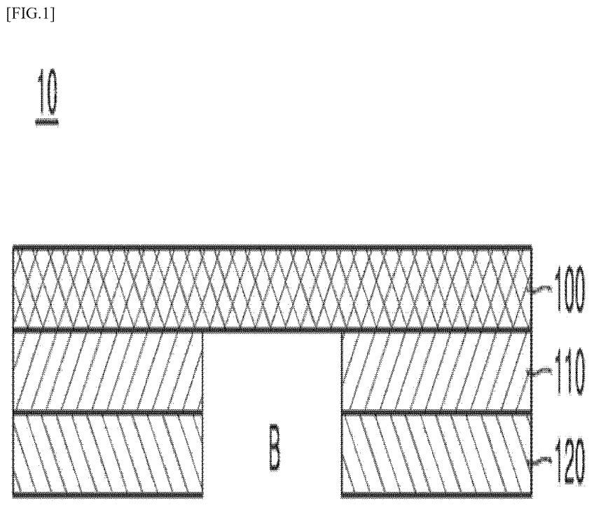

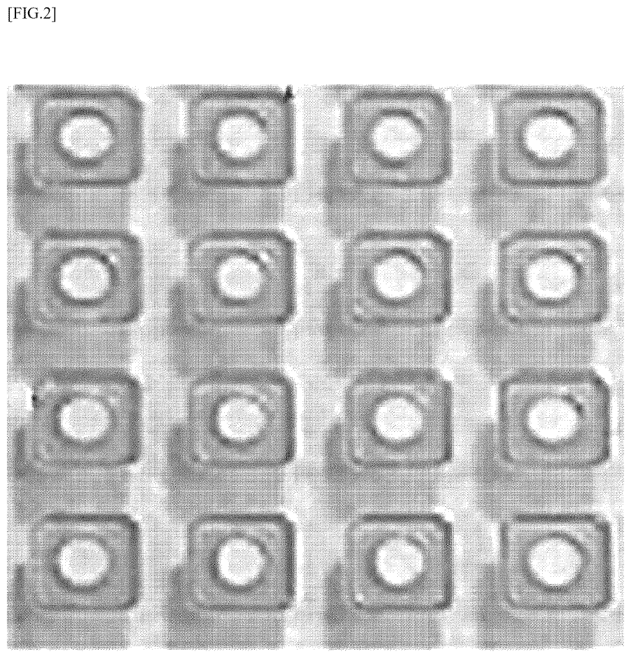

FIG. 1 is a schematic diagram illustrating a nano-membrane assembly 10 including an oil-repellent processed nano-membrane 100, and FIG. 2 is a top view illustrating a group of such nano-membrane assemblies 10.

Referring to FIG. 1, the nano-membrane assembly 10 includes an oil-repellent processed nano-membrane 100, an adhesive layer 110 disposed on one surface of the oil-repellent processed nano-membrane along the periphery of the nano-membrane; and a substrate 120 disposed on the adhesive layer.

The nano-membrane assembly 10 may be manufactured by disposing an adhesive film, in which an adhesive layer 110 is disposed on a substrate 120, on one surface of the oil-repellent processed nano-membrane 100 along its periphery.

The portion of the nano-membrane assembly 10 where the adhesive film is not disposed constitutes a dust-proof part B, and the dust-proof part B not only allows air to pass through but also substantially prevents the passage of micro-sized dust, and has oil-repellent properties that substantially block the passage of moisture. Therefore, when such a nano-membrane assembly is applied to a micro electro mechanical system (MEMS), it may prevent performance degradation of the MEMS due to the influx of foreign substances such as saliva and dust.

The adhesive layer 110 may use a known adhesive that may firmly maintain adhesion between the oil-repellent processed nano-membrane 100 and the MEMS to be subsequently applied. Examples of such adhesives include epoxy adhesives, urethane adhesives, acrylic adhesives, thermosetting adhesives, petroleum resin adhesives, and the like.

For example, the adhesive layer 110 may include a thermosetting adhesive.

The substrate 120 may be a release film. The release film serves as a carrier for disposing the adhesive film on the oil-repellent processed nano-membrane 100, and subsequently prevents contamination of the adhesive layer until the nano-membrane assembly 10 is applied to an acoustic device such as MEMS.

The substrate 120 may be selected from known films that are easily peelable from the adhesive layer 110.

The oil-repellent processed nano-membrane 100 may be a nano-membrane formed of polyimide fibers having an average diameter of 0.1 to 15 μm.

The polyimide fiber refers to a polymer containing an imide bond in its main chain, and may include polyethyleneimine, polyamide-imide, polyetherimide, or a combination thereof.

According to one embodiment, the polyimide fiber may be manufactured by heating a solution containing a polyimide precursor to imidize it.

Polyamic acid may be used as the polyimide precursor.

The polyamic acid solution may be prepared by dissolving a diamine monomer and a dianhydride monomer in a solvent.

The diamine monomer may be one or more selected from the group consisting of 4,4′-oxydianiline (ODA), 1,3-bis(4-aminophenoxy)benzene (RODA), p-phenylene diamine (p-PDA), and o-phenylene diamine (o-PDA), and preferably may be 4,4′-oxydianiline (ODA), p-phenylene diamine (p-PDA), o-phenylene diamine (o-PDA), or a mixture thereof.

The dianhydride monomer may be one or more selected from the group consisting of pyromellitic dianhydride (PMDA), 3,3′,4,4′-benzophenonetetracarboxylic dianhydride (BTDA), 4,4′-oxydiphthalic anhydride (ODPA), 3,4,3′,4′-biphenyltetracarboxylic dianhydride (BPDA), and bis(3,4-dicarboxyphenyl)dimethylsilane dianhydride (SiDA).

The solvent may be one or more selected from the group consisting of m-cresol, n-methyl-2-pyrrolidone (NMP), dimethylformamide (DMF), dimethylacetamide (DMAc), dimethyl sulfoxide (DMSO), acetone, diethyl acetate, tetrahydrofuran (THF), chloroform, and γ-butyrolactone.

The solid content of the polyamic acid solution may be 5 to 30 wt %, and the solution viscosity may be 100 to 500 poise. For example, the solid content of the polyamic acid solution may be 10 to 20 wt %, and the solution viscosity may be 200 to 300 poise. The solution viscosity may be measured by the KS M ISO 2555 method at a temperature of 23° C. The content of solids and the solution viscosity may affect the quality and thickness of the obtained fibers, and when the content of solids and the solution viscosity are satisfied, polyimide fibers of 0.1 to 15 μm may be obtained.

The electrospinning step is a step of preparing a precursor by electrospinning a polyamic acid solution. In the electrospinning step, air may be blown in the direction in which the precursor is discharged to disperse the precursor. The direction of the air may be adjusted at various angles based on the discharge direction of the precursor to disperse the precursor.

During the electrospinning, the polyamic acid solution is spun from the nozzle to produce a precursor, and the precursor is dispersed due to the electrostatic force generated between the spun precursors. At this time, air may be blown towards the precursor at a predetermined angle to disperse the precursor over a wider range. Due to the pressure of the air, the precursor is dispersed over a wider range and accumulated. In this process, the solvent contained in the precursor is removed.

In the present disclosure, by blowing air towards the precursor, the precursor can be dispersed over a wider range, and accordingly, the manufactured nano-membrane 100 has pores with a large diameter and high air permeability.

In addition, in the electrospinning step, high-temperature air may be injected in a horizontal direction to sufficiently remove the solvent, and by adjusting the temperature and amount of the air injected in this horizontal direction and the air for dispersing the precursor, the pore size, porosity of the nano-membrane 100, physical properties of the nano-membrane, etc., can be finely controlled.

For example, the temperature of the air injected in the electrospinning step may be 40° C. to 80° C. When the temperature of the injected air satisfies this range, a porous structure capable of improving dust collection efficiency without sound transmission loss even after oil-repellent treatment is obtained.

The discharge rate in the electrospinning step may be 0.5 to 8 ml/min, for example, the discharge rate may be 2 to 7 ml/min, or 3 to 5 ml/min. By adjusting the discharge rate in the electrospinning step to the above range, a sufficient amount of fiber is discharged, the solvent is sufficiently volatilized and stacked until it is collected on the collector to form a membrane, and as a result, the dust collection efficiency may be increased.

A constant electric field may be applied between the nozzle and the collector to manufacture a nano-membrane having nanofibers of a constant thickness. The strength of the electric field may be 3 to 80 kV. When the strength of the electric field satisfies this range, continuous discharge of a certain amount of spinning solution becomes possible, and the production of a nanofiber web of uniform thickness may be possible. On the other hand, if the strength of the electric field is too low, for example, less than 3 kV, the spinning solution may not be smoothly discharged, causing nozzle clogging. If the strength of the electric field is too high, for example, exceeding 80 kV, the solvent of the scattered fibers reaches the collector without being completely removed, making it difficult to obtain nano-sized fibers.

The nanofiber web may be formed by combining fibers arranged in a certain direction on the collector or randomly arranged fibers. For example, the nanofiber web may have a structure formed by a nonwoven fabric type bond.

The processing step is a step of adjusting the density and thickness of the precursor accumulated in the electrospinning step, and may be performed through a 2-stage continuous calender. The processing step may be performed by applying a pressure of 20 to 200 kgf/cm² at a temperature of 20 to 100° C. For example, the processing step may be performed by applying a pressure of 30 to 150 kgf/cm² at a temperature of 30 to 80° C. By performing the processing step within the aforementioned temperature and pressure ranges, excellent durability may be obtained without sound transmission loss due to pore destruction caused by excessive density increase.

The converting step is a step of determining the shape of the processed precursor. Converting may include slitting to obtain an article of a desired width and cross-cutting such as guillotining to obtain an article of a desired length, and may include, for example, flat-bed or rotary die cutting to obtain an article of a desired shape.

Thereafter, the converted precursor may be imidized to form a strong bond between the fibers.

The imidization may be performed by thermal imidization, chemical imidization, or a combination thereof.

For example, the thermal imidization process may be performed through a process of heating the converted precursor at a temperature of 200° C. to 500° C. for 10 to 30 minutes. For example, it may be performed through a process of heating at a temperature of 350 to 450° C. for 15 to 25 minutes.

When the thermal imidization process is performed within this range, a polyimide nano-membrane with desired physical properties may be obtained without destruction or thermal shrinkage of the polyimide nano-membrane.

For example, the chemical imidization process may be performed by bringing the converted precursor into contact with an acid anhydride such as acetic anhydride or a solvent such as a tertiary amine like pyridine.

The polyimide nano-membrane that has undergone the imidization process may have an imidization rate of 90% or more. By having an imidization rate of 90% or more, it may have excellent heat resistance and durability that can withstand high temperatures of 280° C. or higher.

In addition, the polyimide nano-membrane that has undergone the imidization process may have a porosity of 50 to 90%. For example, the porosity of the polyimide nano-membrane may be 60 to 90%, 70 to 90%, or 60 to 80%.

The polyimide nano-membrane that has undergone the imidization process may have a dust collection efficiency of 95% or more according to the following measurement method. For example, the dust collection efficiency of the polyimide nano-membrane may be 96% or more, 97% or more, 98% or more, or 99% or more.

### [Measurement Method]

Dust size: 0.6 μm; Air flow rate: 32 l/min; Measured according to AFT 8130 with a measurement area of 100 cm².

The polyimide nano-membrane manufactured as described above will be described in more detail below.

The polyimide nano-membrane may have a thickness of 0.5 to 20 μm. The thickness of the nano-membrane may vary depending on the method of coating the nano-membrane and the components contained in the coating solution. However, when measuring the physical properties of the nano-membrane, a thickness difference of 1 to 3 μm does not significantly affect the physical properties of the nano-membrane.

The air permeability of the nano-membrane may be 0.5 to 200 cm³/cm²/sec. For example, the air permeability of the nano-membrane may be 1 to 200 cm³/cm²/sec, 5 to 190 cm³/cm²/sec, 10 to 180 cm³/cm²/sec, 15 to 170 cm³/cm²/sec, 20 to 160 cm³/cm²/sec, 25 to 150 cm³/cm²/sec, or 30 to 140 cm³/cm²/sec.

The basis weight of the nano-membrane may be 0.1 to 10 g/m². For example, the basis weight of the nano-membrane may be 1 to 5 g/m², or 1 to 3 g/m2.

The thermal shrinkage rate of the nano-membrane may be 1% or less at 300° C.

The weight loss rate of the nano-membrane at 300° C. may be 1 wt % or less.

The sound transmission loss of the nano-membrane may be less than 5 dB/Pa at a 94 dB reference.

The polyimide nano-membrane may have oil-repellent functional groups on its surface by treating the surface with an oil-repellent finishing agent. The oil-repellent finishing agent may be a solution in which a fluorine-based compound, a silicone-based compound, and a hydrocarbon-based compound are dissolved in a solvent. At this time, the compound may be included in the solvent at 1 to 20 wt %. For example, the compound may be included in the solvent at 3 to 15 wt %.

For example, the fluorine-based compound may include fluoroalkyl acrylate copolymer, dimethyl perfluorobutylethyl, methyl perfluorobutylethyl, fluoroalkylether copolymer, fluoropolyether compound, perfluoro compound, or a combination thereof.

For example, the fluorine-based compound may be a fluoroalkyl acrylate copolymer.

The perfluoro compound may be perfluorotri-n-butylamine.

For example, the silicone-based compound may include methyl vinyl siloxane copolymer, or a combination thereof, but is not necessarily limited thereto.

For example, the hydrocarbon-based compound may include a C10-18 hydrocarbon compound, or a combination thereof, but is not necessarily limited thereto. The oil-repellent finishing agent may be applied to the surface of the polyimide nano-membrane through spray coating, dip coating, pad-dry coating, gravure coating, plasma treatment, or a combination thereof, and preferably may be treated with the oil-repellent finishing agent by spray coating. By treating the nano-membrane with the oil-repellent finishing agent via spray coating, it may be evenly dispersed and applied to the surface and back surface of the polyimide nano-membrane without blocking the pores of the polyimide nano-membrane, and can provide oil repellency throughout the polyimide nano-membrane.

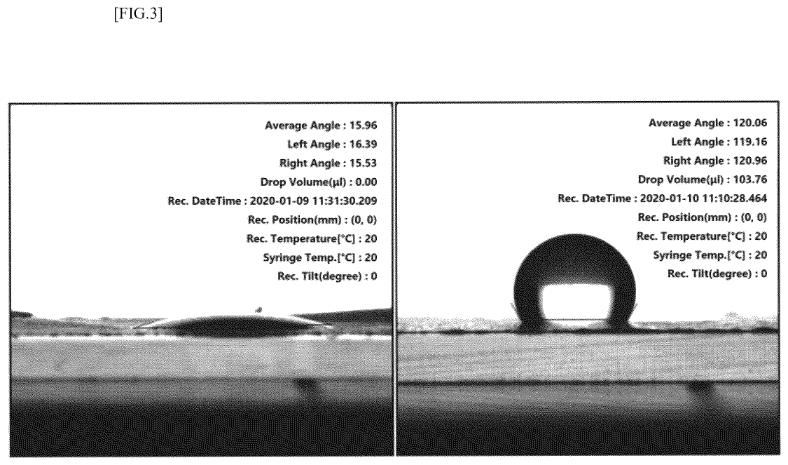

FIG. 3 is a photograph used to measure the contact angle on the surface of a nano-membrane not treated with an oil-repellent finishing agent (left) and a nano-membrane treated with an oil-repellent finishing agent (right).

The nano-membrane treated with the oil-repellent finishing agent may have a contact angle of 90 degrees or more for silicone oil with a surface tension of 20 dyne/cm measured according to ASTM D 5946, as its surface and back surface are uniformly treated.

The nano-membrane treated with the oil-repellent finishing agent may have a contact angle of 90 degrees or more measured according to ASTM D 5946 using ultrapure water with an electrical conductivity of 1 μs/cm or less and a surface tension of 72 dyne/cm, as its surface and back surface are uniformly treated.

The nano-membrane treated with the oil-repellent finishing agent may have a difference of 50 or less, or 45 or less, between the contact angle of silicone oil measured according to ASTM D 5946 and the contact angle measured according to ASTM D 5946 using ultrapure water with an electrical conductivity of 1 μs/cm or less and a surface tension of 72 dyne/cm.

The nano-membrane treated with the oil-repellent finishing agent may achieve simultaneous improvement in the contact angle for moisture such as pure water and the contact angle for oil such as silicone oil, by being treated with the oil-repellent finishing agent.

In addition, by effectively blocking the internal penetration of hydrophilic and lipophilic substances from the outside by the oil-repellent finishing treatment, it also has the effect of improving dust collection efficiency.

Consequently, conventionally, it was not possible to prevent sound transmission loss by adjusting porosity, etc., to improve dust collection efficiency. However, the nano-membrane according to an embodiment of the present disclosure has the effect of improving dust collection efficiency while maintaining sound transmission loss at a level similar to that before the oil-repellent finishing treatment, due to the oil-repellent finishing treatment.

The nano-membrane assembly according to an embodiment of the present disclosure may be used in various electronic devices including MEMS such as mobile phones, electronic pads, microphones, speakers, and the like.

### MODE FOR CARRYING OUT THE INVENTION

Hereinafter, the present disclosure will be described in more detail through specific examples, but the present disclosure is not limited to the following examples.

### Example 1

5L of a polyamic acid solution with a solid content of 11 wt % and a solution viscosity of 250 poise (KS M ISO 2555, 23° C.) was prepared.

The prepared polyamic acid solution was transferred to a solution tank, then supplied to a spinning chamber composed of 20 nozzles and applied with a high voltage of 60 kV through a metering gear pump, and electrospun to prepare a precursor. At this time, the discharge rate was 4 ml/min, the ratio of the distance between the nozzle and the collecting plate to the nozzle tip distance was 1.2, and air at 70° C. was blown in the direction in which the precursor was discharged to disperse the precursor. Thereafter, the precursor was transferred in a roll-to-roll manner, processed by applying a linear pressure of 100 kgf/cm using a 2-stage continuous calender maintained at a temperature of 65° C., and subjected to a converting process to prepare a converted precursor with a thickness of 5 μm and a basis weight of 3 g/m². Thereafter, the converted precursor was transferred in a roll-to-roll manner and imidized for 20 minutes in a continuous heat treatment furnace maintained at a temperature of 400° C. to finally prepare a polyimide nano-membrane with a thickness of 4 μm and a basis weight of 2 g/m².

An oil-repellent nano-membrane was prepared by spray-coating a mixed solution, in which an oil-repellent finishing agent composed of a fluoropolymer was dissolved in isopropyl alcohol at 5 wt %, onto the surface of the polyimide nano-membrane at a rate of 5 cc per minute.

### Examples 2 to 14

Oil-repellent nano-membranes were prepared in the same manner as in Example 1 by modifying the reaction conditions as shown in Table 1 below. In Table 1 below, perfluoro compound is perfluorotri-n-butylamine.

### Comparative Example 1

5L of a polyamic acid solution with a solid content of 11 wt % and a solution viscosity of 250 poise (KS M ISO 2555, 23° C.) was prepared.

The prepared polyamic acid solution was transferred to a solution tank, then supplied to a spinning chamber composed of 20 nozzles and applied with a high voltage of 60 kV through a metering gear pump, and electrospun to prepare a precursor. At this time, the discharge rate was 4 ml/min, the ratio of the distance between the nozzle and the collecting plate to the nozzle tip distance was 1.2, and air at 70° C. was blown in the direction in which the precursor was discharged to disperse the precursor. Thereafter, the precursor was transferred in a roll-to-roll manner, processed by applying a linear pressure of 100 kgf/cm using a 2-stage continuous calender maintained at a temperature of 65° C., and subjected to a converting process to prepare a converted precursor with a thickness of 5 μm and a basis weight of 3 g/m². Thereafter, the converted precursor was transferred in a roll-to-roll manner and imidized for 20 minutes in a continuous heat treatment furnace maintained at a temperature of 300° C. to finally prepare a polyimide nano-membrane with a thickness of 4 μm and a basis weight of 2 g/m².

### Comparative Examples 2 to 7

Oil-repellent nano-membranes were prepared in the same manner as in Example 1 by modifying the reaction conditions as shown in Table 2 below. In Table 2 below, perfluoro compound is perfluorotri-n-butylamine.

### Comparative Example 8

Polyvinylidene difluoride (PVDF) was dissolved in dimethylformamide (DMF) solvent to prepare 5L of an electrospinning solution with a solid content of 15 wt % and a solution viscosity of 250 poise (KS M ISO 2555, 23° C.).

The prepared electrospinning solution was transferred to a solution tank, then supplied to a spinning chamber composed of 20 nozzles and applied with a high voltage of 60 kV through a metering gear pump, and electrospun to prepare a PVDF nano-membrane. At this time, the discharge rate was 4 ml/min, and the ratio of the distance between the nozzle and the collecting plate to the nozzle tip distance was 1.2.

TABLE 1

| | | | | | Electrospinning | | | | |
|---|---|---|---|---|---|---|---|---|---|
| | Raw Material | | | | | | | | Air |
| | | Solid | | Production | | | Discharge | | Injection |
| | Raw | Content | Viscosity | Amount | | Voltage | Rate | Distance | Temp |
| Category | Material | (%) | (poise) | (L) | Nozzle | (kV) | (ml/min) | Ratio | (° C.) |
| Ex. 1 | Polyamic | 11 | 250 | 5 | 20 | 60 | 4 | 1.2 | 70 |
| | acid | | | | | | | | |
| Ex. 2 | Polyamic | 11 | 250 | 5 | 20 | 60 | 4 | 1.2 | 70 |
| | acid | | | | | | | | |
| Ex. 3 | Polyamic | 11 | 250 | 5 | 20 | 60 | 4 | 1.2 | 70 |
| | acid | | | | | | | | |
| Ex. 4 | Polyamic | 11 | 250 | 5 | 20 | 60 | 4 | 1.2 | 70 |
| | acid | | | | | | | | |
| Ex. 5 | Polyamic | 11 | 250 | 5 | 20 | 60 | 4 | 1.2 | 70 |
| | acid | | | | | | | | |
| Ex. 6 | Polyamic | 11 | 250 | 5 | 20 | 60 | 4 | 1.2 | 70 |
| | acid | | | | | | | | |
| Ex. 7 | Polyamic | 11 | 250 | 5 | 20 | 60 | 4 | 1.2 | 70 |
| | acid | | | | | | | | |
| Ex. 8 | Polyamic | 11 | 250 | 5 | 20 | 60 | 4 | 1.2 | 70 |
| | acid | | | | | | | | |
| Ex. 9 | Polyamic | 11 | 250 | 5 | 20 | 60 | 4 | 1.2 | 70 |
| | acid | | | | | | | | |
| Ex. 10 | Polyamic | 10.5 | 200 | 5 | 20 | 65 | 3 | 1.2 | 70 |
| | acid | | | | | | | | |
| Ex. 11 | Polyamic | 11 | 250 | 5 | 20 | 50 | 5 | 1.2 | 60 |
| | acid | | | | | | | | |
| Ex. 12 | Polyamic | 11 | 250 | 5 | 20 | 60 | 4 | 1.2 | 60 |
| | acid | | | | | | | | |

| | Electrospinning | | Imidization | | Oil-Repellent Treatment | | |
|---|---|---|---|---|---|---|---|
| | | As-spun | | PI | Oil | | |
| | Calender | Membrane | Imidization | Membrane | Repellent | | |
| | (° C., | (μm, | (° C., | (μm, | Agent | Concentration | |
| Category | kgf/cm) | g/m²) | min) | g/m2) | Component | (%) | Method |
| Ex. 1 | 65, | 5, | 400, | 4, | Fluoroalkyl | 5 | Spray |
| | 100 | 3 | 20 | 2 | acrylate | | coating |
| | | | | | copolymer | | |
| Ex. 2 | 65, | 5, | 400, | 4, | Fluoroalkyl | 15 | Spray |
| | 100 | 3 | 20 | 2 | acrylate | | coating |
| | | | | | copolymer | | |
| Ex. 3 | 65, | 5, | 400, | 4, | Fluoroalkyl | 3 | Spray |
| | 100 | 3 | 20 | 2 | acrylate | | coating |
| | | | | | copolymer | | |
| Ex. 4 | 65, | 5, | 400, | 4, | Perfluoro | 5 | Spray |
| | 100 | 3 | 20 | 2 | compound, | | coating |
| | | | | | (C10~C18) | | |
| Ex. 5 | 65, | 5, | 400, | 4, | Fluoroalkyl | 5 | Dip |
| | 100 | 3 | 20 | 2 | acrylate | | coating |
| | | | | | copolymer | | |
| Ex. 6 | 65, | 5, | 400, | 4, | Fluoroalkyl | 5 | Gravure |
| | 100 | 3 | 20 | 2 | acrylate | | coating |
| | | | | | copolymer | | |
| Ex. 7 | 65, | 5, | 300, | 4, | Fluoroalkyl | 5 | Spray |
| | 100 | 3 | 20 | 2 | acrylate | | coating |
| | | | | | copolymer | | |
| Ex. 8 | 65, | 5, | 500, | 4, | Fluoroalkyl | 5 | Spray |
| | 100 | 3 | 20 | 2 | acrylate | | coating |
| | | | | | copolymer | | |
| Ex. 9 | 65, | 5, | 300, | 4, | Perfluoro | 4 | Spray |
| | 100 | 3 | 20 | 2 | compound, | | coating |
| | | | | | (C10~C18) | | |
| Ex. 10 | 65, | 5, | 400, | 3, | Perfluoro | 1 | Spray |
| | 100 | 3 | 20 | 2 | compound | | coating |
| | | | | | (C10~C18) | | |
| Ex. 11 | 65, | 5, | 300, | 3, | Fluoroalkyl | 20 | Dip |
| | 100 | 3 | 20 | 2 | acrylate | | coating |
| | | | | | copolymer | | |
| Ex. 12 | 65, | 5, | 300, | 4, | Fluoroalkyl | 10 | Spray |
| | 100 | 3 | 20 | 2 | acrylate | | coating |
| | | | | | copolymer | | |

TABLE 2

| | | | | | Electrospinning | | | | |
|---|---|---|---|---|---|---|---|---|---|
| | Raw Material | | | | | | | | Air |
| | | Solid | | Production | | | Discharge | | Injection |
| | Raw | Content | Viscosity | Amount | | Voltage | Rate | Distance | Temp |
| Category | Material | (%) | (poise) | (L) | Nozzle | (kV) | (ml/min) | Ratio | (° C.) |
| Comp. | Polyamic | 11 | 250 | 5 | 20 | 60 | 4 | 1.2 | 70 |
| Ex. 1 | acid | | | | | | | | |
| Comp. | Polyamic | 11 | 250 | 5 | 20 | 60 | 4 | 1.2 | 70 |
| Ex. 2 | acid | | | | | | | | |
| Comp. | Polyamic | 11 | 250 | 5 | 20 | 60 | 4 | 1.2 | 70 |
| Ex. 3 | acid | | | | | | | | |
| Comp. | Polyamic | 11 | 250 | 5 | 20 | 60 | 4 | 1.2 | 70 |
| Ex. 4 | acid | | | | | | | | |
| Comp. | Polyamic | 11 | 250 | 5 | 20 | 60 | 4 | 1.2 | 70 |
| Ex. 5 | acid | | | | | | | | |
| Comp. | Polyamic | 13 | 350 | 5 | 30 | 65 | 5 | 1.5 | 50 |
| Ex. 6 | acid | | | | | | | | |
| Comp. | Polyamic | 12 | 300 | 5 | 20 | 55 | 5 | 1.2 | 60 |
| Ex. 7 | acid | | | | | | | | |
| Comp. | PVDF | 15 | 250 | 5 | 20 | 60 | 4 | 1.2 | X |
| Ex. 8 | | | | | | | | | |

| | Electrospinning | | Imidization | | Oil-Repellent Treatment | | |
|---|---|---|---|---|---|---|---|
| | | As-spun | Imidi- | PI | Oil | | |
| | Calender | Membrane | Zation | Membrane | Repellent | | |
| | (° C., | (μm, | (° C., | (μm, | Agent | Concentration | |
| Category | kgf/cm) | g/m²) | min) | g/m²) | Component | (%) | Method |
| Comp. | 65, | 5, | 300, | 4, | X | X | X |
| Ex. 1 | 100 | 3 | 20 | 2 | | | |
| Comp. | 65, | 5, | 400, | 4, | Fluoroalkyl | 25 | Spray |
| Ex. 2 | 100 | 3 | 20 | 2 | acrylate | | coating |
| | | | | | copolymer | | |
| Comp. | 65, | 5, | 400, | 4, | X | X | X |
| Ex. 3 | 100 | 3 | 20 | 2 | | | |
| Comp. | 65, | 5, | 180, | 4, | Fluoroalkyl | 5 | Spray |
| Ex. 4 | 100 | 3 | 20 | 2 | acrylate | | coating |
| | | | | | copolymer | | |
| Comp. | 65, | 5, | 600, | Carbonized | Fluoroalkyl | 5 | Spray |
| Ex. 5 | 100 | 3 | 20 | (crumbled) | acrylate | | coating |
| | | | | | copolymer | | |
| Comp. | 70, | 6, | 400, | 4, | Fluoroalkyl | 40 | Dip |
| Ex. 6 | 100 | 4 | 20 | 3 | acrylate | | coating |
| | | | | | copolymer | | |
| Comp. | 25, | 5, | 300, | 4, | Fluoroalkyl | 0.5 | Gravure |
| Ex. 7 | 100 | 3 | 20 | 2 | acrylate | | coating |
| | | | | | copolymer | | |
| Comp. | X | X | X | X | X | X | X |
| Ex. 8 | | | | | | | |

### Evaluation of Nano-Membrane

The basis weight, thickness, porosity, air permeability, pore size, contact angle (oil), sound transmission loss, dust collection efficiency (dust proofness), and thermal shrinkage rate of the nano-membranes of Examples 1 to 12 and Comparative Examples 1 to 8 were measured according to the following methods, and the results are shown in Table 3.
(1) Basis weight: KS K 0514 or ASTM D 3776
(2) Thickness: KS K 0506 or KS K ISO 9073-2, ISO 4593
3) Porosity: Calculated as the ratio of air volume to the total volume of the nanofiber membrane according to Equation 1 below (total volume was calculated by preparing a rectangular or circular sample and measuring its length, width, and thickness, and air volume was calculated by subtracting the polymer volume, obtained by back-calculating from the density after measuring the mass of the sample, from the total volume).

$$Porosity ( \% ) = [ 1 - ( A / B ) ] \times 100 = \{ 1 - [ ( C / D ) / B ] \} \times 100 \qquad [ Equation 1 ]$$

In Equation 1, A is the density of the nano-membrane, B is the density of the nano-membrane polymer, C is the weight of the nano-membrane, and D is the volume of the nano-membrane.
(4) Air permeability: Measured under conditions of ASTM D 737, area 38 cm³, static pressure 125 Pa (cm³/cm²/sec) may be converted to CFM, the conversion factor is 0.508016, and its unit is ft³/ft²/min (CFM).
(5) Average pore diameter: Using a capillary flow porometer (CFP) specified in ASTM F316, the average pore size and pore size distribution were measured from the diameter of the limiting pore, which is the pore size at the narrowest section.
(6) Contact angle (oil): Measured using SEO Phoenix 300 Touch (equipment name) according to the method specified in ASTM D 5946. A certain amount of silicone oil (surface tension 20 dyne/cm @20° C.) was dropped onto the nano-membrane, and the angle formed by the static liquid droplet and the surface was measured. A larger contact angle of silicone oil means greater oil repellency.
(7) Sound transmission loss: The change in microphone sensitivity was checked in the frequency range of the speaker (100~20,000 Hz), and the degree of sound loss was evaluated by measuring the sensitivity when the nano-membrane assembly was attached to the MEMS that recognizes microphone sensitivity and when it was not attached.
(8) Dust collection efficiency (dust proofness): Measured using AFT 8130 with dust size 0.6 μm, air flow rate 32 l/min, and measurement area 100 cm².
(9) Thermal shrinkage rate (%): After heat treatment in an oven at a temperature of 300° C.±2° C. for 30±2 minutes, the sample was left for 24 hours under conditions of 23° C.±2° C. temperature and 50%+5% humidity (relative humidity), and then the change in length was measured.
(10) Weight loss rate: 0.5 g of each sample was prepared, and heat was applied to the sample using a TGA analyzer (Thermoplus EVO II TG8120, Rigaku) under a nitrogen atmosphere by raising the temperature from room temperature to 800° C. at a rate of 20° C./min, and the corresponding weight change was measured.

TABLE 3

| | Specification | | | | | | | | | |
|---|---|---|---|---|---|---|---|---|---|---|
| | | | | | | | Sound | | | |
| | | | | | | | Transmission | Dust | Thermal | Weight |
| | Unit | | | Air | Pore | Contact | Loss | Collection | Shrinkage | Loss |
| | Weight | Thickness | Porosity | Permeability | Size | Angle | (dB/pa@ | Efficiency | Rate | Rate |
| Category | (g/m²) | (μm) | (%) | (cm³/cm²/sec) | (μm) | (oil) | 94 dB) | (%) | (%) | (%) |
| Ex. 1 | 2 | 3 | 85 | 120 | 10 | 95 | 1.5 | 99 | <1 | <1 |
| Ex. 2 | 2.2 | 5 | 60 | 98 | 6 | 100 | 2 | 95.3 | <1 | <1 |
| Ex. 3 | 2 | 4 | 90 | 121 | 10 | 98 | 1 | 98.9 | <1 | <1 |
| Ex. 4 | 2 | 4 | 90 | 125 | 10 | 105 | 1 | 99 | <1 | <1 |
| Ex. 5 | 2.2 | 5 | 55 | 105 | 7 | 96 | 1.5 | 95 | <1 | <1 |
| Ex. 6 | 2.1 | 4 | 75 | 103 | 7 | 98 | 1.5 | 93 | <1 | <1 |
| Ex. 7 | 2.1 | 4 | 85 | 118 | 10 | 100 | 1.5 | 99 | <1 | <1 |
| Ex. 8 | 2.1 | 4 | 83 | 115 | 10 | 99 | 1.5 | 99 | <1 | <1 |
| Ex. 9 | 2 | 3 | 85 | 118 | 9 | 100 | 1.5 | 99 | <1 | <1 |
| Ex. 10 | 2 | 3 | 90 | 120 | 10 | 91 | 1 | 98.5 | <1 | <1 |
| Ex. 11 | 2.1 | 3 | 55 | 110 | 5 | 112 | 3.5 | 99.5 | <1 | <1 |
| Ex. 12 | 2.2 | 3 | 85 | 116 | 7 | 100 | 3 | 97 | <1 | <1 |
| Comp. | 2 | 4 | 85 | 120 | 10 | 6 | 1.5 | 87 | <1 | <1 |
| Ex. 1 | | | | | | | | | | |
| Comp. | 2.1 | 5 | 50 | 87 | 2 | 56 | 7.5 | 75 | <1 | 1.5 |
| Ex. 2 | | | | | | | | | | |
| Comp. | 2 | 4 | 85 | 120 | 10 | 6 | 1.5 | 87 | <1 | <1 |
| Ex. 3 | | | | | | | | | | |
| Comp. | 2.1 | 5 | 55 | 93 | 3 | 65 | 6.3 | 75 | <1 | <1 |
| Ex. 4 | | | | | | | | | | |
| Comp. | — | — | — | — | — | — | — | — | — | — |
| Ex. 5 | | | | | | | | | | |
| Comp. | 3.2 | 4 | 50 | 35 | 2 | 130 | 8.5 | 99.9 | <1 | <1 |
| Ex. 6 | | | | | | | | | | |
| Comp. | 2 | 4 | 65 | 130 | 15 | 43 | 0.5 | 95 | <1 | <1 |
| Ex. 7 | | | | | | | | | | |
| Comp. | 2 | 4 | 80 | 30 | 1.5 | 30 | 1 | 89.6 | 15 | >30 |
| Ex. 8 | | | | | | | | | | |

As shown in Table 3, Example 1, which is an oil-repellent treated nano-membrane, showed significantly increased contact angles for oil compared to untreated nano-membranes (Comparative Examples 1, 3), despite having similar levels of air permeability, porosity, and sound transmission loss rate, and thereby achieved a dust collection efficiency exceeding 98%. In addition, due to its excellent heat resistance, it was confirmed that there was virtually no loss of the membrane during high-temperature operations. Also, it may be confirmed that Example 1, with an oil repellent agent concentration of 5 wt %, has no sound transmission loss and very excellent air permeability compared to Comparative Example 2 with 25 wt % and Comparative Example 6 with 40 wt %.

Furthermore, it may be confirmed that Example 1, with an oil repellent agent concentration of 5 wt %, exhibits a higher contact angle (oil) than Comparative Example 7 with 0.5 wt %.

In addition, Comparative Example 5, with an imidization temperature of 600° C., was carbonized and its physical properties could not be measured, and Comparative Example 4, with 180° C., showed a sound transmission loss more than 4 times that of Example 1 with 400° C.

Meanwhile, it may be confirmed that Example 1, which used polyamic acid, has significantly superior air permeability, dust collection efficiency, etc., compared to Comparative Example 8, which used PVDF.

As such, the nano-membrane according to the present disclosure may be used without quality degradation in MEMS manufacturing processes that involve high-temperature operations. Furthermore, it is recognized as overcoming the existing technical challenge where an increase in sound transmission loss was inevitable when adjusting porosity and pore size to improve the dust collection efficiency of conventional polyimide nano-membranes.

### INDUSTRIAL APPLICABILITY

The present disclosure may provide a nano-membrane in which quality degradation does not occur even in a high-temperature process because it is made of polyimide fibers formed by electrospinning a polyimide precursor.

1. A nano-membrane formed of polyimide fibers, comprising:
an oil-repellent coating layer on a surface or a back surface thereof, wherein the nano-membrane has:
a contact angle of 90 degrees or more for silicone oil with a surface tension of 20 dyne/cm measured according to ASTM D 5946, and
a dust collection efficiency of 95% or more according to the following measurement method.
[Measurement Method]
Dust size: 0.6 μm; Air flow rate: 32 l/min; Measured according to AFT 8130 with a measurement area of 100 cm².

2. The nano-membrane of claim 1, wherein the membrane is manufactured by electrospinning.

3. The nano-membrane of claim 1, wherein the oil-repellent coating layer comprises at least one selected from the group consisting of a fluorine-based compound, a silicone-based compound, and a hydrocarbon-based compound.

4. The nano-membrane of claim 3, wherein the fluorine-based compound comprises fluoroalkyl acrylate copolymer, dimethyl perfluorobutylethyl, methyl perfluorobutylethyl, fluoroalkylether copolymer, perfluoro compound, or a combination thereof.

5. The nano-membrane of claim 3, wherein the silicone-based compound comprises methyl vinyl siloxane copolymer, or a combination thereof.

6. The nano-membrane of claim 3, wherein the hydrocarbon-based compound comprises a C10-18 hydrocarbon compound, or a combination thereof.

7. The nano-membrane of claim 1, wherein the polyimide fiber comprises polyethyleneimine, polyamide-imide, polyetherimide, or a combination thereof.

8. The nano-membrane of claim 1, wherein the nano-membrane has a thermal shrinkage rate of 1% or less at 300° C.

9. The nano-membrane of claim 1, wherein the nano-membrane has a weight loss rate of 1 wt % or less at 300° C.

10. The nano-membrane of claim 1, wherein the nano-membrane has a sound transmission loss of less than 5 dB/Pa at a 94 dB reference.

11. A nano-membrane assembly, comprising:
a substrate;
the nano-membrane according to claim 1; and
an adhesive layer interposed between the substrate and the nano-membrane.

12. An electronic device comprising the nano-membrane according to claim 1.

13. A method for manufacturing a nano-membrane, the method comprising:
electrospinning a polyamic acid solution to prepare a precursor;
adjusting the density and thickness of the precursor;
converting to determine the shape of the precursor;
imidizing the converted precursor to obtain a nano-membrane precursor; and
treating the nano-membrane precursor with an oil-repellent finishing agent to introduce functional groups to the surface, wherein:
the oil-repellent finishing agent is a solution containing 1 to 20 wt % of at least one selected from the group consisting of a fluorine-based compound, a silicone-based compound, and a hydrocarbon-based compound, and
the imidization is performed at 200° C. to 500° C. for 10 to 30 minutes, wherein in the electrospinning step:
air is blown in the direction in which the precursor is discharged, and
the nano-membrane has a dust collection efficiency of 95% or more according to the following measurement method.
[Measurement Method]
Dust size: 0.6 μm; Air flow rate: 32 l/min; Measured according to AFT 8130 with a measurement area of 100 cm²,
the carbon black particles have an aspect ratio of 1.0 to 5,
has a water pressure resistance of 5,000 mmH2O to 15,000 mmH2O, and
an air permeability of 1 cm³/cm²/sec (ccs) to 10 cm³/cm²/sec, a method for manufacturing a nano-membrane.
